(19) United States
(12) Patent Application Publication
(10) Pub. No.: US 2026/0309423 A1
(43) Pub. Date: Oct. 8, 2026

(54) HEAT TREATMENT APPARATUS

(71) Applicant: Tokyo Electron Limited, Tokyo (JP)

(72) Inventor: Naomi ONODERA, Oshu City (JP)

(21) Appl. No.: 19/577,935

(22) Filed: Mar. 25, 2026

(30) Foreign Application Priority Data
Apr. 4, 2025 (JP) 2025-062177

(51) Int. Cl. F27D 99/00; F27D 1/18

(52) U.S. Cl. CPC F27D 99/0073; F27D 1/1808

(57) ABSTRACT

A heat treatment apparatus includes a cylindrical reaction tube having an opening at a lower end thereof, a lid configured to close the opening, and an annular seal member held by the lid between the cylindrical reaction tube and the lid. The lid includes an annular buffer material fixed to the lid between the cylindrical reaction tube and the lid on a radially outward side of the annular seal member, and the annular buffer material includes a plurality of divided buffer materials which is divided along a circumferential direction.

### CROSS-REFERENCE TO RELATED APPLICATION

This application is based upon and claims the benefit of priority from Japanese Patent Application No. 2025-062177, filed on Apr. 4, 2025, the entire contents of which are incorporated herein by reference.

### TECHNICAL FIELD

The present disclosure relates to a heat treatment apparatus.

### BACKGROUND

Patent Document 1 discloses a heat treatment apparatus having a configuration in which an airtight seal and a buffer material are provided between a reaction tube and a lid that closes a furnace opening of the reaction tube. Patent Document 2 discloses a heat treatment apparatus having a configuration in which an airtight member and a contact-regulating member are provided between a processing container and a lid that closes a furnace opening of the processing container.

### PRIOR ART DOCUMENTS

### Patent Documents

Patent Document 1: Japanese Laid-Open Patent Publication No. 2014-090145

Patent Document 2: Japanese Laid-Open Patent Publication No. 2008-177524

### SUMMARY

According to an embodiment of the present disclosure, a heat treatment apparatus includes: a cylindrical reaction tube having an opening at a lower end thereof; a lid configured to close the opening; and an annular seal member held by the lid between the cylindrical reaction tube and the lid, wherein the lid includes an annular buffer material fixed to the lid between the cylindrical reaction tube and the lid on a radially outward side of the annular seal member, and the annular buffer material includes a plurality of divided buffer materials which is divided along a circumferential direction.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a cross-sectional view showing a heat treatment apparatus according to an embodiment.

FIG. 2 is a first enlarged cross-sectional view showing region A1 in FIG. 1.

FIG. 3 is a second enlarged cross-sectional view showing region A1 in FIG. 1.

FIG. 4 is a third enlarged cross-sectional view showing region A1 in FIG. 1.

FIG. 5 is a plan view showing an example of a buffer material.

FIG. 6 is an enlarged perspective view showing region A2 in FIG. 5.

FIG. 7 is an enlarged plan view showing region A2 in FIG. 5.

FIG. 8 is a side view when seen in a direction of arrow A3 in FIG. 7.

### DETAILED DESCRIPTION

Hereinafter, non-limiting exemplary embodiments of the present disclosure will be described with reference to the accompanying drawings. In all the accompanying drawings, the same or corresponding reference numerals are used to designate the same or corresponding members or components, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Heat Treatment Apparatus

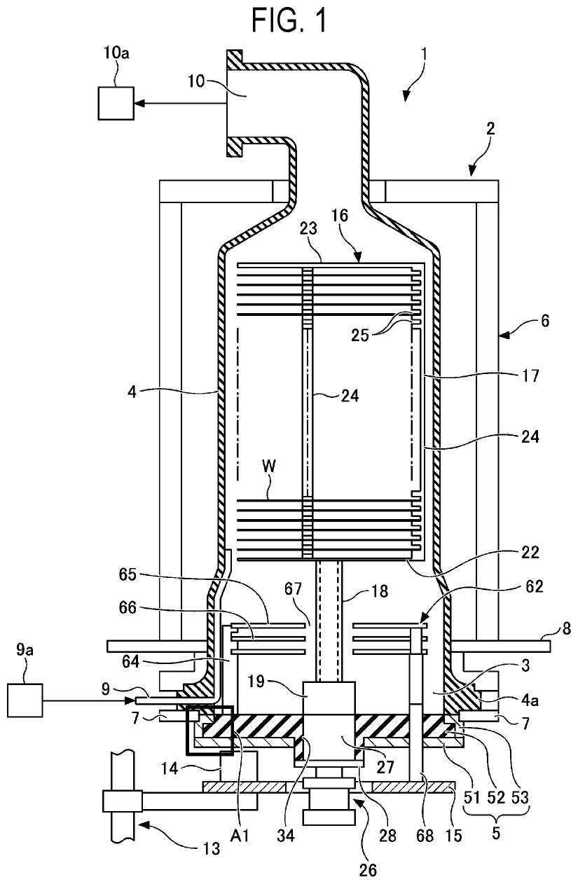

FIG. 1 is a cross-sectional view showing a heat treatment apparatus 1 according to an embodiment. As shown in FIG. 1, the heat treatment apparatus 1 includes a heat treatment furnace 2. The heat treatment apparatus 1 performs heat treatment on substrates W accommodated in the heat treatment furnace 2. The substrates W are, for example, semiconductor wafers. The heat treatment furnace 2 includes a reaction tube 4, a lid 5, and a heater 6.

The reaction tube 4 has a cylindrical shape. The reaction tube 4 has an opening 3 at a lower end thereof. The opening 3 is also called a furnace opening. The reaction tube 4 is made of, for example, quartz. A bottom flange 4a is provided at the lower end of the reaction tube 4. The bottom flange 4a is an outward-oriented flange. The bottom flange 4a is held at a bottom of a base plate 8 via a flange holding member 7. The flange holding member 7 and the base plate 8 are made of a metal such as stainless steel or the like.

A gas supply pipe 9 is attached to the bottom flange 4a. A gas supplier 9a is connected to the gas supply pipe 9. The gas supply pipe 9 supplies a processing gas introduced from the gas supplier 9a into the reaction tube 4. The gas supplier 9a may include a gas source, a valve, and a mass flow controller. The number of gas supply pipes 9 may be one or two or more.

The top of the reaction tube 4 is gradually tapered, and is provided with an exhaust port 10. An exhauster 10a is connected to the exhaust port 10. The exhauster 10a reduces an internal pressure of the reaction tube 4. The exhauster 10a may include a vacuum pump and a pressure controller.

The lid 5 is configured to be movable up and down by a lifting mechanism 13. The lid 5 opens and closes the opening 3 of the reaction tube 4. The lid 5 closes the opening 3 of the reaction tube 4 when it is raised. The lid 5 opens the opening 3 of the reaction tube 4 when it is lowered. The lid 5 has, for example, a substantially disk-like shape. Details of the lid 5 will be described later. The lid is held on a holding plate 15 via a plurality of buffer mechanisms 14. The holding plate 15 is connected to the lifting mechanism 13. A rotary introduction mechanism 26 is provided at a center of a lower portion of the lid 5. The rotary introduction mechanism 26 has a rotary shaft 27 for rotating a boat 16.

The boat 16 is made of, for example, quartz. The boat 16 includes a boat body 17 and a leg 18. The boat body 17 supports a plurality of substrates W, for example, 25 to 200 substrates W, in multiple stages in a horizontal posture so as to be spaced apart from each other in a vertical direction. The leg 18 supports the boat body 17. For example, the boat body 17 and the leg 18 may be formed integrally with each other. The leg 18 is connected to the rotary shaft 27.

The boat body 17 includes a bottom plate 22, a top plate 23, and a plurality of support columns 24. The plurality of support columns 24 are provided between the bottom plate 22 and the top plate 23 to connect the bottom plate 22 and the top plate 23. The bottom plate 22, the top plate 23, and the plurality of support columns 24 may be formed integrally with each other. The plurality of support columns 24 are arranged at predetermined intervals in a circumferential direction so as to surround the substrates W. The plurality of support columns 24 are not arranged on a front side (left side in FIG. 1). This is because the substrates W are loaded and unloaded by a transfer mechanism (not shown) via the front side. Each support column 24 has grooves 25 formed to hold the plurality of substrates W in multiple stages.

The rotary introduction mechanism 26 includes a rotary shaft 27 and a housing 28. The rotary shaft 27 is provided integrally with the lid 5 at the center of the lower portion of the lid 5. The housing 28 has a cylindrical shape. The housing 28 rotatably supports the rotary shaft 27. A bottomed cylindrical rotary cylinder (not shown) having a rotary shaft integrally formed at its axial center is rotatably provided on a lower outer periphery of the housing 28. The rotary shaft, which stands upright from the center of the bottom of the rotary cylinder, airtightly penetrates the housing 28 via a sealing means such as an O-ring or a magnetic fluid seal. A motor (not shown) is connected to the rotary cylinder via a belt. Thus, the rotary shaft is rotationally driven. A shaft hole 34 through which the rotary shaft 27 passes is provided at the center of the lid 5.

A furnace-opening heating mechanism 62 is provided on the lid 5. The furnace-opening heating mechanism 62 includes a plurality of support columns 64, a heating resistor 65, and a heat shield plate 66. The plurality of support columns 64 are provided to stand on an upper surface of the lid 5 at appropriate intervals in the circumferential direction. The heating resistor 65 is provided at an upper end of the support columns 64. The heat shield plate 66 is provided below the heating resistor 65. A plurality of heat shield plates 66 may be provided. In FIG. 1, two heat shield plates 66 are provided.

The support columns 64 and the heat shield plate 66 are made of, for example, quartz. The heating resistor 65 and the heat shield plate 66 are provided with through-holes 67 through which the leg 18 including the flange 19 of the boat 16 passes. A guide pipe 68 for guiding a cable that supplies electric power to the heating resistor 65 is provided to airtightly penetrate the lid 5 from the holding plate 15.

The heater 6 is installed on a base plate 8. The heater 6 is provided around the reaction tube 4. The heater 6 heats an interior of the reaction tube 4 to a predetermined temperature. The predetermined temperature is, for example, 300 degrees C or higher and 1,200 degrees C or lower.

### Lid

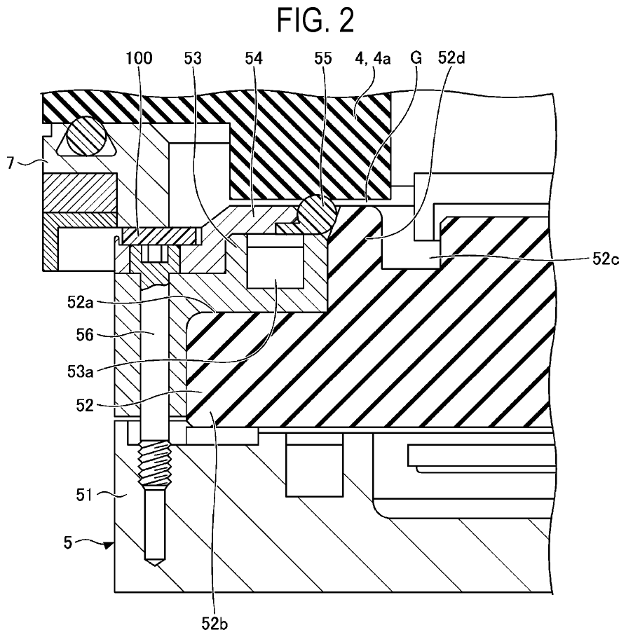

FIGS. 2 to 4 are enlarged cross-sectional views showing region A1 in FIG. 1. As shown in FIGS. 2 to 4, the lid 5 includes a first lid 51, a second lid 52, a first ring 53, a second ring 54, and a buffer material 100.

The first lid 51 has a substantially circular disk shape. The first lid 51 is made of metal such as stainless steel or the like.

The second lid 52 has a substantially circular disk shape. The second lid 52 is made of quartz. The second lid 52 is supported by the first lid 51. The second lid 52 closes the opening 3 of the reaction tube 4. A downwardly-depressed annular recess 52a is formed in an upper outer periphery of the second lid 52. A flange 52b is provided on a lower outer periphery of the second lid 52.

The first ring 53 is positioned in the annular recess 52a to hold the flange portion 52b of the second lid 52. A seal member 55 that comes into contact with a lower surface of an opening end of the reaction tube 4 is provided on a top of the first ring 53. The seal member 55 has a Q-shaped cross section. A refrigerant flow path 53a is provided inside the first ring 53. The seal member 55 may be cooled by allowing a refrigerant such as cooling water or the like to flow through the refrigerant flow path 53a. The first ring 53 has a substantially inverted L-shaped cross section. The first ring 53 has an annular shape that covers the flange portion 52b around the second lid 52. While holding the flange portion 52b, the first ring 53 is detachably fixed to the first lid 51 by mounting screws 56 (FIG. 2). A plurality of mounting screws 56 may be provided along the circumferential direction.

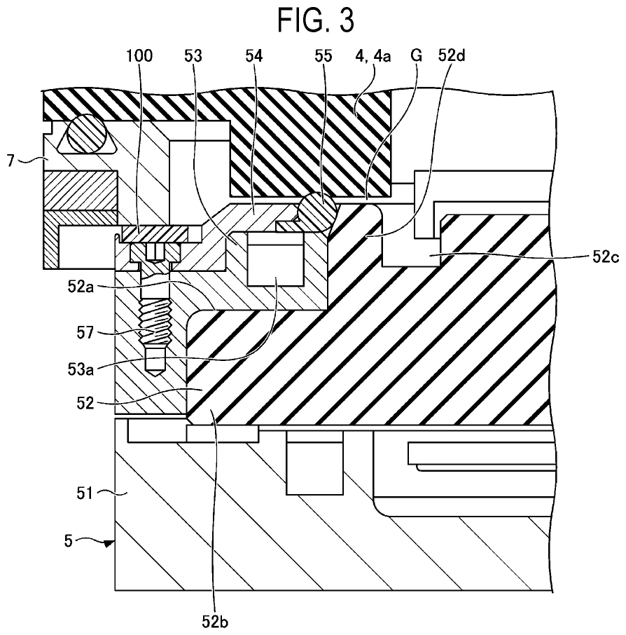

The second ring 54 is fixed on the first ring 53. The second ring 54, together with the second lid 52 and the first ring 53, holds the seal member 55. The second ring 54 is detachably fixed to the first ring 53 by mounting screws 57 (FIG. 3). A plurality of mounting screws 57 may be provided along the circumferential direction.

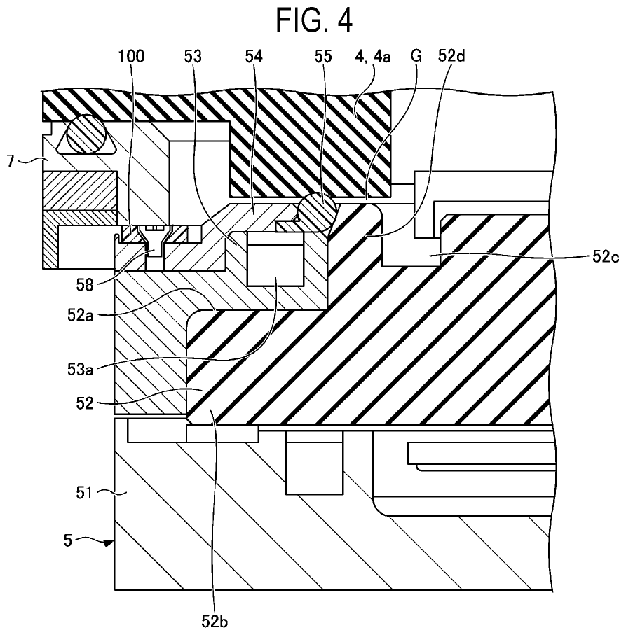

The buffer material 100 is detachably fixed on the second ring 54 by mounting screws 58 (FIG. 4). When the opening 3 of the reaction tube 4 is sealed with the lid 5, the second ring 54 comes into contact with the lower surface of the flange holding member 7 via the buffer material 100, and a gap G is formed between the second lid 52 and the bottom flange 4a of the reaction tube 4. This makes it possible to prevent damage to the second lid 52 and the reaction tube 4 and generation of particles due to contact between the second lid 52 and the reaction tube 4. Details of the buffer material 100 will be described later.

A circumferential groove 52c is provided radially inward of the seal member 55 on the upper surface of the second lid 52. The circumferential groove 52c blocks heat that would otherwise be transferred in a radially outward direction from the center of the second lid 52 along the upper surface of the second lid 52. This prevents heat from being transferred from the center of the second lid 52 to the seal member 55. A circumferential protrusion 52d is provided radially outward of the circumferential groove 52c on the upper surface of the second lid 52. The gap G between the second lid 52 and the bottom flange 4a is located on the circumferential protrusion 52d.

### Buffer Material

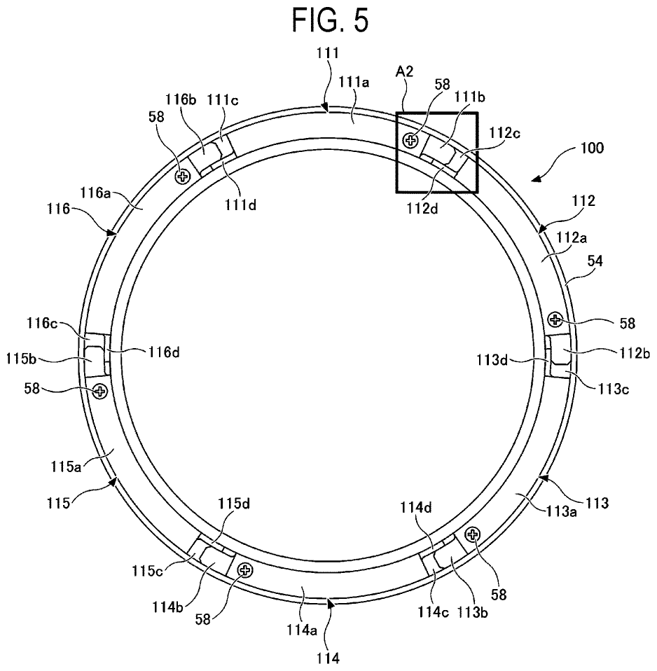

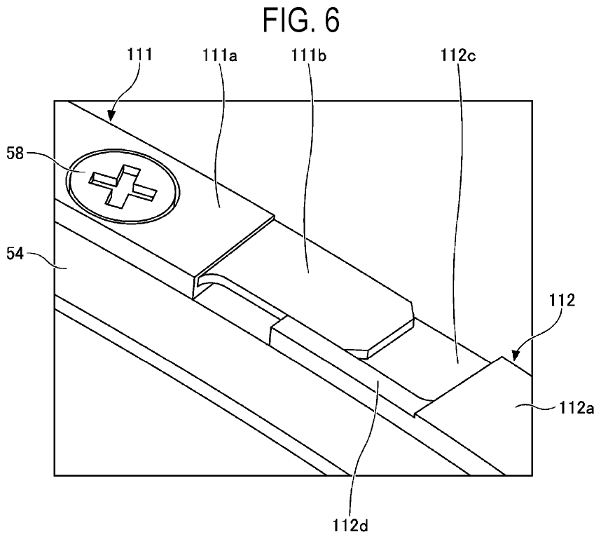

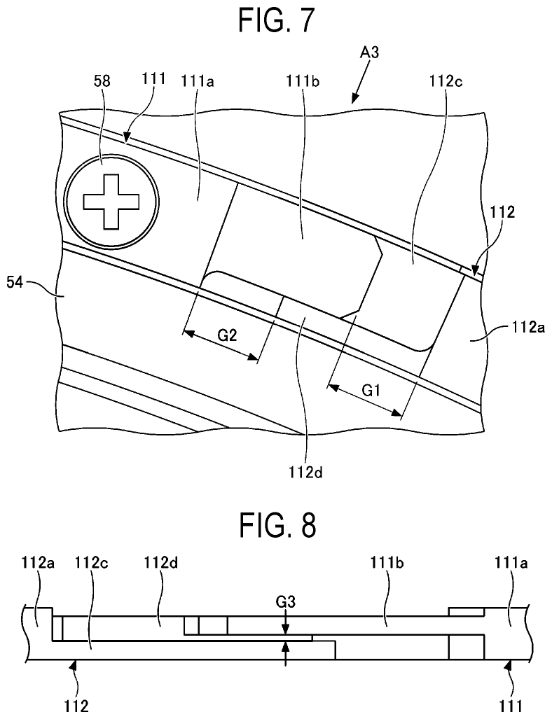

FIG. 5 is a plan view showing an example of the buffer material 100. FIG. 6 is an enlarged perspective view showing region A2 in FIG. 5. FIG. 7 is an enlarged plan view showing region A2 in FIG. 5. FIG. 8 is a side view when seen in a direction of arrow A3 in FIG. 7.

The buffer material 100 is provided radially outward of the seal member 55 between the flange holding member 7 and the second ring 54. The buffer material 100 is fixed to the second ring 54. The buffer material 100 has an annular shape. The buffer material 100 is made of a resin. The resin is, for example, polyimide. The buffer material 100 includes divided buffer materials 111 to 116 that are divided into multiple pieces (for example, six pieces) in the circumferential direction. In this case, it is possible to suppress deformation of the buffer material 100 due to thermal expansion.

The divided buffer material 111, the divided buffer material 112, the divided buffer material 113, the divided buffer material 114, the divided buffer material 115, and the divided buffer material 116 are provided in the named order along the circumferential direction.

A configuration of the divided buffer material 111, a configuration of the divided buffer material 112, and a positional relationship between the divided buffer material 111 and the divided buffer material 112 will be described below by way of example.

The divided buffer material 111 includes a main body portion 111a, a first flat plate portion 111b, a second flat plate portion 111c, and a protrusion portion 111d.

The main body portion 111a has a flat plate shape. The main body portion 111a has an arc shape in a plan view. The main body portion 111a has a first end and a second end opposite the first end. The first end is adjacent to the divided buffer material 112. The second end is adjacent to the divided buffer material 116. The first end of the main body portion 111a is fixed to the second ring 54 by a mounting screw 58, and the second end is a free end. In this case, it is possible to absorb deformation due to thermal expansion of the divided buffer material 111.

The first flat plate portion 111b has a flat plate shape. The first flat plate portion 111b extends circumferentially from the first end of the main body portion 111a. An upper surface of the first flat plate portion 111b is lower than an upper surface of the main body portion 111a. In other words, a stepped portion where the upper surface of the first flat plate portion 111b is lower than the upper surface of the main body portion 111a is located between the upper surface of the first flat plate portion 111b and the upper surface of the main body portion 111a. In this case, a pressure is less likely to be applied to the upper surface of the first flat plate portion 111b, which makes it possible to suppress deformation of the first flat plate portion 111b. Corners at the tip of the first flat plate portion 111b have a chamfered shape. In this case, when the divided buffer material 111 is deformed due to thermal expansion or the like, it is possible to suppress the first flat plate portion 111b from getting caught on other components. The chamfered shape is, for example, a C-chamfered shape. The chamfered shape may also be an R-chamfered shape. A base end of the first flat plate portion 111b may have a curved surface shape.

The second flat plate portion 111c has a flat plate shape. The second flat plate portion 111c extends circumferentially from the second end of the main body portion 111a. An upper surface of the second flat plate portion 111c is lower than the upper surface of the main body portion 111a. In other words, a stepped portion where the upper surface of the second flat plate portion 111c is lower than the upper surface of the main body portion 111a is located between the upper surface of the second flat plate portion 111c and the upper surface of the main body portion 111a. In this case, a pressure is less likely to be applied to the upper surface of the second flat plate portion 111c, which makes it possible to suppress deformation of the second flat plate portion 111c.

The protrusion portion 111d protrudes upward from the upper surface of the second flat plate portion 111c in the radially outward direction. The protrusion portion 111d extends circumferentially from the second end of the main body portion 111a. An upper surface of the protrusion portion 111d is lower than the upper surface of the main body portion 111a. In other words, a stepped portion where the upper surface of the protrusion portion 111d is lower than the upper surface of the main body portion 111a is located between the upper surface of the protrusion portion 111d and the upper surface of the main body portion 111a. In this case, a pressure is less likely to be applied to the upper surface of the protrusion portion 111d, which makes it possible to suppress deformation of the protrusion portion 111d.

The divided buffer material 112 includes a main body portion 112a, a first flat plate portion 112b, a second flat plate portion 112c, and a protrusion portion 112d.

The main body portion 112a has a flat plate shape. The main body portion 112a has an arc shape in a plan view. The main body portion 112a has a first end and a second end opposite the first end. The first end is adjacent to the divided buffer material 113. The second end is adjacent to the divided buffer material 111. The first end of the main body portion 112a is fixed to the second ring 54 by a mounting screw 58, and the second end is a free end. In this case, it is possible to absorb deformation due to thermal expansion of the divided buffer material 112.

The first flat plate portion 112b has a flat plate shape. The first flat plate portion 112b extends circumferentially from the first end of the main body portion 112a. An upper surface of the first flat plate portion 112b is lower than an upper surface of the main body portion 112a. In other words, a stepped portion where the upper surface of the first flat plate portion 112b is lower than the upper surface of the main body portion 112a is located between the upper surface of the first flat plate portion 112b and the upper surface of the main body portion 112a. In this case, a pressure is less likely to be applied to the upper surface of the first flat plate portion 112b, which makes it possible to suppress deformation of the first flat plate portion 112b. Corners at the tip of the first flat plate portion 112b have a chamfered shape. In this case, when the divided buffer material 112 is deformed due to thermal expansion or the like, it is possible to suppress the first flat plate portion 112b from getting caught on other components. The chamfered shape is, for example, a C-chamfered shape. The chamfered shape may also be an R-chamfered shape.

The second flat plate portion 112c has a flat plate shape. The second flat plate portion 112c extends circumferentially from the second end of the main body portion 112a. An upper surface of the second flat plate portion 112c is lower than the upper surface of the main body portion 112a. In other words, a stepped portion where the upper surface of the second flat plate portion 112c is lower than the upper surface of the main body portion 112a is located between the upper surface of the second flat plate portion 112c and the upper surface of the main body portion 112a. In this case, a pressure is less likely to be applied to the upper surface of the second flat plate portion 112c, which makes it possible to suppress deformation of the second flat plate portion 112c.

The protrusion portion 112d protrudes upward from the upper surface of the second flat plate portion 112c in a radially inward direction. The protrusion portion 112d extends circumferentially from the second end of the main body portion 112a. An upper surface of the protrusion portion 112d is lower than the upper surface of the main body portion 112a. In other words, a stepped portion where the upper surface of the protrusion portion 112d is lower than the upper surface of the main body portion 112a is located between the upper surface of the protrusion portion 112d and the upper surface of the main body portion 112a. In this case, a pressure is less likely to be applied to the upper surface of the protrusion portion 112d, which makes it possible to suppress deformation of the protrusion portion 112d.

The first flat plate portion 111b of the divided buffer material 111 extends from the first end of the main body portion 111a toward the second end of the main body portion 112a of the divided buffer material 112. A circumferential end surface of the first flat plate portion 111b of the divided buffer material 111 faces a circumferential end surface of the second end of the main body portion 112a of the divided buffer material 112. A first gap G1 exists between the circumferential end surface of the first flat plate portion 111b of the divided buffer material 111 and the circumferential end surface of the second end of the main body portion 112a of the divided buffer material 112. In this case, it is possible to absorb circumferential deformation of the divided buffer materials 111 and 112 due to thermal expansion or the like.

The second flat plate portion 112c of the divided buffer material 112 extends from the second end of the main body portion 112a toward the first end of the main body portion 111a of the divided buffer material 111. A circumferential end surface of the second flat plate portion 112c of the divided buffer material 112 faces a circumferential end surface of the first end of the main body portion 111a of the divided buffer material 111. A second gap G2 exists between the circumferential end surface of the second flat plate portion 112c of the divided buffer material 112 and the circumferential end surface of the first end of the main body portion 111a of the divided buffer material 111. In this case, it is possible to absorb circumferential deformation of the divided buffer materials 111 and 112 due to thermal expansion or the like.

At least a portion of the lower surface of the first flat plate portion 111b of the divided buffer material 111 faces the upper surface of the second flat plate portion 112c of the divided buffer material 112. In this case, when an upward warping force acts on the second flat plate portion 112c, the first flat plate portion 111b presses the upper surface of the second flat plate portion 112c downward, thereby preventing the second flat plate portion 112c from warping upward.

A third gap G3 exists between the lower surface of the first flat plate portion 111b of the divided buffer material 111 and the upper surface of the second flat plate portion 112c of the divided buffer material 112. In this case, when horizontal positions of the first flat plate portion 111b and the second flat plate portion 112c are changed relative to each other due to thermal expansion or the like, it is possible to prevent the lower surface of the first flat plate portion 111b from rubbing against the upper surface of the second flat plate portion 112c.

At least a portion of an inner peripheral surface of the first flat plate portion 111b of the divided buffer material 111 faces an outer peripheral surface of the protrusion portion 112d of the divided buffer material 112. The second end of the divided buffer material 112 is a free end. Therefore, when the divided buffer material 112 is deformed due to thermal expansion or the like, the other end of the divided buffer material 112 may protrude in the radially outward direction. In contrast, when the outer peripheral surface of the protrusion portion 112d of the divided buffer material 112 faces at least a portion of the inner peripheral surface of the first flat plate portion 111b of the divided buffer material 111, the outer peripheral surface of the protrusion portion 112d comes into contact with the inner peripheral surface of the first flat plate portion 111b. Accordingly, it is possible to prevent the divided buffer material 112 from protruding in the radially outward direction.

Configurations of the divided buffer materials 113 to 116 may be similar to those of the divided buffer materials 111 and 112. That is, the divided buffer material 113 includes a main body portion 113a, a first flat plate portion 113b, a second flat plate portion 113c, and a protrusion portion 113d. The divided buffer material 114 includes a main body portion 114a, a first flat plate portion 114b, a second flat plate portion 114c, and a protrusion portion 114d. The divided buffer material 115 includes a main body portion 115a, a first flat plate portion 115b, a second flat plate portion 115c, and a protrusion portion 115d. The divided buffer material 116 includes a main body portion 116a, a first flat plate portion 116b, a second flat plate portion 116c, and a protrusion portion 116d.

A positional relationship between the divided buffer material 112 and the divided buffer material 113, a positional relationship between the divided buffer material 113 and the divided buffer material 114, a positional relationship between the divided buffer material 114 and the divided buffer material 115, a positional relationship between the divided buffer material 115 and the divided buffer material 116, and a positional relationship between the divided buffer material 116 and the divided buffer material 111 may be similar to the positional relationship between the divided buffer material 111 and the divided buffer material 112.

According to the present disclosure in some embodiments, it is possible to reduce deformation of a buffer material.

The embodiments disclosed herein should be considered to be exemplary and not limitative in all respects, and the above-described embodiments may be omitted, substituted, or modified in various ways without departing from the scope and spirit of the appended claims.

What is claimed is:

1. A heat treatment apparatus, comprising:
a cylindrical reaction tube having an opening at a lower end thereof;
a lid configured to close the opening; and
an annular seal member held by the lid between the cylindrical reaction tube and the lid,
wherein the lid includes an annular buffer material fixed to the lid between the cylindrical reaction tube and the lid on a radially outward side of the annular seal member, and
wherein the annular buffer material includes a plurality of divided buffer materials which is divided along a circumferential direction.

2. The heat treatment apparatus of claim 1, wherein each of the plurality of divided buffer materials includes a main body portion having a first end and a second end opposite the first end, and
wherein the first end of the main body portion is fixed to the lid, and the second end is a free end.

3. The heat treatment apparatus of claim 2, wherein each of the plurality of divided buffer materials includes:
a first flat plate portion extending from the first end of the main body portion along the circumferential direction; and
a second flat plate portion extending from the second end of the main body portion along the circumferential direction, and
wherein at least a portion of a lower surface of the first flat plate portion of one of two divided buffer materials adjacent to each other among the plurality of divided buffer materials in the circumferential direction faces an upper surface of the second flat plate portion of the other of the two divided buffer materials.

4. The heat treatment apparatus of claim 3, wherein a circumferential end surface of the first flat plate portion of the one of the two divided buffer materials adjacent to each other in the circumferential direction faces a circumferential end surface of the main body portion of the other of the two divided buffer materials, and
wherein a first gap exists between the circumferential end surface of the first flat plate portion of the one of the two divided buffer materials and the circumferential end surface of the main body portion of the other of the two divided buffer materials.

5. The heat treatment apparatus of claim 3, wherein a circumferential end surface of the main body portion of the one of the two divided buffer materials adjacent to each other in the circumferential direction faces a circumferential end surface of the second flat plate portion of the other of the two divided buffer materials, and
wherein a second gap exists between the circumferential end surface of the main body portion of the one of the two divided buffer materials and the circumferential end surface of the second flat plate portion of the other of the two divided buffer materials.

6. The heat treatment apparatus of claim 3, wherein a third gap exists between the lower surface of the first flat plate portion and the upper surface of the second flat plate portion, which face each other.

7. The heat treatment apparatus of claim 3, wherein an upper surface of the first flat plate portion is lower than an upper surface of the main body portion.

8. The heat treatment apparatus of claim 3, wherein each of the plurality of divided buffer materials includes a protrusion portion protruding upward from the upper surface of the second flat plate portion in a radially inward direction, and
wherein an outer peripheral surface of the protrusion portion of the other of the two divided buffer materials faces at least a portion of an inner peripheral surface of the first flat plate portion of the one of the two divided buffer materials.

9. The heat treatment apparatus of claim 8, wherein an upper surface of the protrusion portion is lower than an upper surface of the main body portion.

10. The heat treatment apparatus of claim 1, wherein the annular buffer material is made of a resin.

11. The heat treatment apparatus of claim 1, wherein the lid includes:
a first lid made of metal;
a second lid supported by the first lid and configured to close the opening;
a first ring having an annular shape and configured to surround the second lid; and
a second ring fixed to the first ring and configured to hold the annular seal member together with the second lid and the first ring, and
wherein the annular buffer material is fixed to the second ring.

12. The heat treatment apparatus of claim 1, wherein the cylindrical reaction tube has a bottom flange made of quartz, and
wherein at least a portion of a lower surface of the bottom flange is in contact with the annular seal member.

13. The heat treatment apparatus of claim 12, wherein the cylindrical reaction tube includes a metal-made flange holder configured to hold the bottom flange, and
wherein at least a portion of a lower surface of the metal-made flange holder faces an upper surface of the annular buffer material.
